(19) United States
(12) Patent Application Publication
(10) Pub. No.: US 2012/0068213 A1
(43) Pub. Date: Mar. 22, 2012

(54) LIGHT EMISSIVE CERAMIC LAMINATE AND METHOD OF MAKING SAME

(75) Inventors: Bin Zhang, San Diego, CA (US); Guang Pan, Carlsbad, CA (US); Hiroaki Miyagawa, Oceanside, CA (US); Hironaka Fujii, Carlsbad, CA (US); Rajesh Mukherjee, Irvine, CA (US); Toshitaka Nakamura, Osaka (JP)

(73) Assignee: NITTO DENKO CORPORATION, Osaka (JP)

(21) Appl. No.: 13/235,147

(22) Filed: Sep. 16, 2011

Related U.S. Application Data
(60) Provisional application No. 61/384,536, filed on Sep. 20, 2010.

(51) Int. Cl. H01L 33/50; B32B 37/14; B32B 37/06; B32B 19/00; B32B 3/00

(52) U.S. Cl. 257/98; 428/690; 428/336; 156/67; 257/E33.061

(57) ABSTRACT

A laminated composite includes a wavelength-converting layer and a non-emissive blocking layer, wherein the emissive layer includes a garnet host material and an emissive guest material, and the non-emissive blocking layer includes a non-emissive blocking material. The metallic element constituting the non-emissive blocking material has an ionic radius which is less than about 80% of an ionic radius of an A cation element when the garnet or garnet-like host material is expressed as A₃B₅O₁₂ and/or an element constituting the emissive guest material, and the non-emissive blocking layer is substantially free of the emissive guest material migrated through an interface between the emissive layer and the non-emissive blocking layer.

### CROSS-REFERENCE TO RELATED APPLICATIONS

This application claims the benefit of U.S. Provisional Application No. 61/384,536, filed Sep. 20, 2010, the disclosure of which is herein incorporated by reference in its entirety.

### BACKGROUND OF THE INVENTION

1. Field of the Invention

This disclosure relates to luminescent layers suitable for light-emitting devices, such as translucent ceramic sheets composed of emissive and non-emissive blocking layers and methods of making the same.

2. Description of the Related Art

Solid state light-emitting devices such as light-emitting diodes (LEDs), organic light-emitting diodes (OLEDs) sometimes called organic electroluminescent devices (OELs), and inorganic electroluminescent devices (IEL) have been widely utilized for various applications such as flat panel displays, indicators for various instruments, signboards, and ornamental illuminations, etc. As the emission efficiency of these light-emitting devices continues to improve, applications that require much higher luminance intensity, such as automobile headlights and general lighting, may soon become feasible. For these applications, white LED is one of the promising candidates and has attracted much attention.

Conventional white LED's are manufactured based on a combination of blue LED and yellow light-emitting YAG:Ce phosphor powder used as a wavelength-converting material dispersed in an encapsulant resin such as epoxy and silicone, as disclosed in U.S. Pat. No. 5,998,925 and U.S. Pat. No. 6,069,440. The wavelength-converting material is so disposed as to absorb some part of the blue LED light-emission and re-emit the light at a different wavelength as yellow or green-yellow light. The combination of the blue light from the LED and the green-yellow light from the phosphor results in perceived white light. A typical device structure is shown in FIGS. 1A and 1B. A submount 10 shown in FIG. 1A has a blue LED 11 mounted thereon, covered with a transparent matrix 13 in which YAG:Ce phosphor powder 12 is dispersed and encapsulated by a protective resin 15. As shown in FIG. 1B, the blue LED 11 is covered with a transparent matrix 13 in which YAG:Ce phosphor powder 12 is disposed. However, since the particle size of YAG:Ce phosphor powder utilized for this system is around 1-10 μm, the YAG:Ce powder 12 dispersed in the transparent matrix 13 can cause strong light scattering. As a result, as shown in FIG. 2, a considerable portion of both incident light 18 from the blue LED 11 and yellow light 19 emitted from the YAG:Ce powder 12 ends up being backscattered and dissipated, causing a loss of white light emission.

As shown in FIG. 3, one solution to this problem is to form a monolithic ceramic member 22 as a composite wavelength-converting element. The ceramic member 22 can be constituted by plural ceramic layers of single or multiple phosphor layers 20, and transparent layers 24a, 24b (e.g., 24r, 24s, 24t, 24u). A lighting device 21 incorporates the composite wave-length converting element 22 positioned adjacent to a light source 26, e.g., a semiconductor light emitting diode, and in the path of light 28 emitted from the light source 26, to receive the emitted light within the emissive layer 20. It has been recognized that thin layers of phosphor ceramics with sufficiently high activator content having a thickness on the order of tens of microns/micrometers can reduce production costs significantly. Nevertheless, while being appropriate for color conversion, the thin phosphor layers are rendered fragile and difficult to handle. The configurations shown in FIG. 3 provide a solution responsive to this problem, i.e., the phosphor layer 20 is combined with the thin ceramic layers 24a, 24b to facilitate handling. The transparent ceramic layers 24a, 24b may be constituted by, for example, a material the same as the host material of the wavelength-converting material, but may be devoid of any guest or dopant material (e.g., U.S. Pat. No. 7,361,938). These laminated layers may also be in the form of luminescent ceramic cast tapes, which can be laminated and co-fired (U.S. Pat. No. 7,514,721 and U.S. Published Application No. 2009/0108507).

However, co-fired laminated layers suffer from additional problems. Since some of these laminated layers are generally formed from garnet powders produced through solid state reaction, the present inventors recognized that using these garnet powders can result in poor luminosity once the guest materials diffuse into the laminated layers, even though the cost of manufacture is low. Furthermore, interlayer diffusion of the guest material also alters the demanded and actual activating guest or dopant concentration in the emissive layer, contributing to degraded device performance as well. Furthermore, the diffusion of the dopant into low quality garnet powders contributes to a decreased efficiency of the device.

Thus, the present inventors recognized that there is a need for an effective way to enhance the light output from white LEDs while minimizing the backscattering loss by using ceramic composites and minimizing production costs with a laminated structure. The present inventors also recognized that there is a need for a laminated ceramic structure which does not sacrifice luminescent efficiency and device performance due to interlayer guest material diffusion.

### SUMMARY F THE INVENTION

Some embodiments provide a ceramic wavelength-converting element comprising: at least a first emissive layer comprising a garnet or garnet-like host material and an emissive guest material; at least a first and second non-emissive blocking layer comprising a non-emissive blocking material having elements with an ionic radius which is about 80% or less of an ionic radius of an A cation element when the garnet or garnet-like host material is expressed as A₃B₅O₁₂ and/or an element constituting the emissive guest material (each A and B is composed of one or two or more elements), the first emissive layer disposed between the first and second non-emissive blocking layers. In some embodiments, the non-emissive blocking layer is a transparent layer comprising or consisting essentially of Al₂O₃. In some embodiment, the first non-emissive blocking layer is used alone without the second non-emissive blocking layer. In some embodiments, the garnet or garnet-like host material is selected from Y₃Al₅O₁₂, Lu₃Al₅O₁₂, Ca₃Sc₂Si₃O₁₂, (Y,Tb)₃Al₅O₁₂, (Y, Gd)₃(Al Ga)₅O₁₂, Lu₂CaSi₃Mg₂O₁₂, and Lu₂CaAl₄SiO₁₂. In some embodiments, the emissive guest material is Ce.

As illustrated in FIG. 14, some embodiments provide a method of making the ceramic wavelength-converting element, comprising the steps of providing a first emissive layer comprising a garnet or garnet-like host material and an emissive guest material; providing a first and second non-emissive blocking layers comprising a non-emissive blocking material having an ionic radius less than that of the emissive guest material, the first emissive layer disposed between the first and second non-emissive blocking layers; applying a thermal treatment concurrently to the first emissive layer and first and second non-emissive blocking layers, said thermal treatment being sufficient to concurrently sinter the three layers into a single ceramic wavelength-converting element, wherein the first and second non-emissive blocking layers remain substantially emissive guest material free.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not necessarily to scale.

FIGS. 1A and 1B illustrate a cross-sectional view of conventional white LED devices.

FIG. 2 illustrates how the light emitted from a blue LED device is backscattered by micron-sized yellow phosphor powder in the conventional white LED devices.

FIG. 3 illustrates a schematic cross-sectional view of a conventional ceramic laminated structure having an emissive host-guest layer and non-emissive host-only layers (using the same host as that in the emissive host-guest layer without guest material).

FIG. 4 illustrates a schematic cross-sectional view of an embodiment of a ceramic laminated structure having an emissive layer and non-emissive blocking layers (without guest material).

FIG. 5 illustrates a schematic cross-sectional view of an embodiment of a ceramic laminated structure having plural emissive layers and plural non-emissive blocking layers (without guest material).

FIG. 6 illustrates a schematic cross-sectional view of an embodiment of a wavelength-converting ceramic laminated structure comprising an emissive YAG:Ce layer and a non-emissive YAG (without an emissive guest material [Ce]).

FIG. 7 illustrates a TOF-SIMS spectrum depicting the diffusion of various ions from the emissive layer/non-emissive blocking layer interface of the laminated ceramic structure of FIG. 6.

FIG. 8 illustrates a schematic cross-sectional view of an embodiment of a wavelength-converting ceramic laminated structure comprising an emissive YAG:Ce layer and a non-emissive Al₂O₃ layer (without an emissive guest material [Ce]).

FIG. 9 illustrates a TOF-SIMS spectrum depicting the diffusion of various ions from the emissive layer/non-emissive blocking layer interface of the laminated ceramic structure of FIG. 8.

FIG. 10 illustrates a schematic cross-sectional view of another embodiment made in accordance with the disclosed embodiments.

FIG. 11 illustrates a schematic cross-sectional view of another embodiment made in accordance with the disclosed embodiments.

FIG. 12 illustrates a schematic cross-sectional view of another embodiment made in accordance with the disclosed embodiments.

FIG. 13 illustrates a schematic cross-sectional view of another embodiment made in accordance with the disclosed embodiments.

FIG. 14 illustrates a process diagram showing an embodiment of one of the processes used for fabricating a disclosed embodiment.

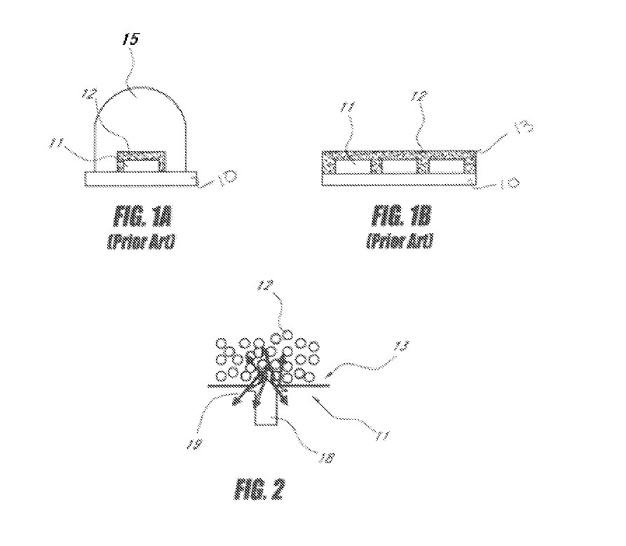

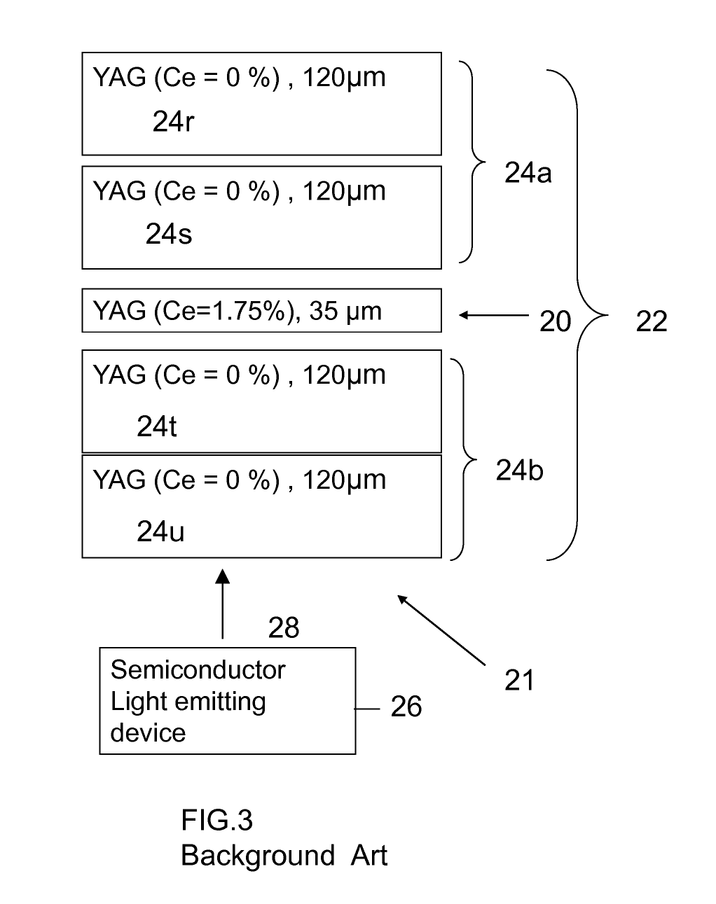

### DETAILED DESCRIPTION

The present inventors have discovered that selecting the elements of the non-emissive blocking layer material based upon the ionic radii of the material surprisingly reduces the diffusion of the emissive guest material from the juxtaposed emissive layer into the non-emissive blocking layer, providing better wavelength conversion efficiency and increased device performance. For example, the present inventors have learned that Al₂O₃ can be used to replace YAG as the non-emissive blocking layer material. Due, at least in part, to the smaller ionic radius of Al³⁺ relative to Ce³⁺ ion, diffusion of the guest material into Al₂O₃ is reduced. Al₂O₃ is a much less expensive material for use in light emitting devices, even compared with regularly purified undoped YAG. Moreover, the non-emissive blocking layer of Al₂O₃ can be laminated and co-fired with the YAG emissive layer to get substantially high transparency. In some embodiments, Al₂O₃ can be used as a non-emissive blocking layer for other garnet or garnet-like phosphor layers which use Ce as the primary guest material.

By using Al₂O₃ in the non-emissive blocking layer, the guest material, e.g., Ce, can be more greatly constrained within the emissive layer. The low cost of Al₂O₃, as well as the possibility of using higher Ce concentration thus leading to a thinner emissive layer, can result in further production cost reduction. Moreover, Al₂O₃ can be used as a non-emissive blocking layer for any garnet or garnet-like phosphor layers which use Ce as the primary guest material.

Several methods exist for the preparation of emissive materials. Any suitable methods including conventional methods can be used. For example, phosphors are synthesized by wet chemical coprecipitation, hydrothermal synthesis, supercritical synthesis, solid state reaction, combustion, laser pyrolysis, flame spray, spray pyrolysis and/or plasma synthesis. To get high wavelength conversion efficiency, phosphor materials require ultrahigh purity (e.g., higher than 99.99%) and defect-free crystalline structure, which usually means high synthesis cost. Among these synthesis processes, plasma synthesis, especially radio frequency (RF) inductively coupled thermal plasma synthesis, leads to exceptional purity of end products since no combustible gases (fuels such as methane in flame spray) are used and the products do not come in contact with any electrodes.

For example, as taught in patent publication WO2008112710 A1, size-controlled, high purity and high luminous efficiency phosphor particles can be produced by passing a precursor solution in atomized form into the hot zone of a RF thermal plasma torch and thereby nucleating phosphor particles. These particles can then be collected on suitable filter elements. For example, cerium-doped yttrium-aluminum oxide particles can be synthesized using an aqueous solution of stoichiometric quantities of yttrium nitrate, aluminum nitrate and cerium nitrate by atomizing this solution via two-fluid atomization in the center of a RF plasma torch thereby evaporating and decomposing the precursors followed by nucleating Y—Al—O particles. These particles can be extracted from the effluent gases using an appropriate filtering mechanism. The collected particles when subjected to thermal annealing in an appropriate furnace at temperatures above 1000° C. are completely converted to phase pure cerium-doped yttrium aluminum garnet (Y₃Al₅O₁₂) particles. Dopant levels are determined by any desired application and a skilled artisan in the art can appreciate that a change of the guest material level can be achieved without deviating from the fundamentals of this concept. The present inventors have also found that RF plasma synthesized phosphors have the highest wavelength conversion efficiency compared to other methods. Details of the synthesis and other important things in the disclosed embodiments can be found in WO2008112710 A1, the disclosure of which is hereby incorporated by reference in its entirety.

The disclosed embodiments are described in detail below. In the present disclosure where conditions and/or structures are not specified, the skilled artisan in the art can readily provide such conditions and/or structures as a matter of routine experimentation in view of the present disclosure and, as necessary, the disclosure of WO2008/112710 for producing cerium-doped YAG powder using RF thermal plasma synthesis, which is incorporated by reference in its entirety. Further, in order to obtain a ceramic layer formed of Ce-doped YAG powder, providing a ceramic composite laminate having a wavelength conversion efficiency (WCE) of at least 0.65, the dispersion of the dopant or activator within the ceramic can be used as a control variable as disclosed in co-pending U.S. provisional application No. 61/301,515, the disclosure of which is herein incorporated by reference in its entirety.

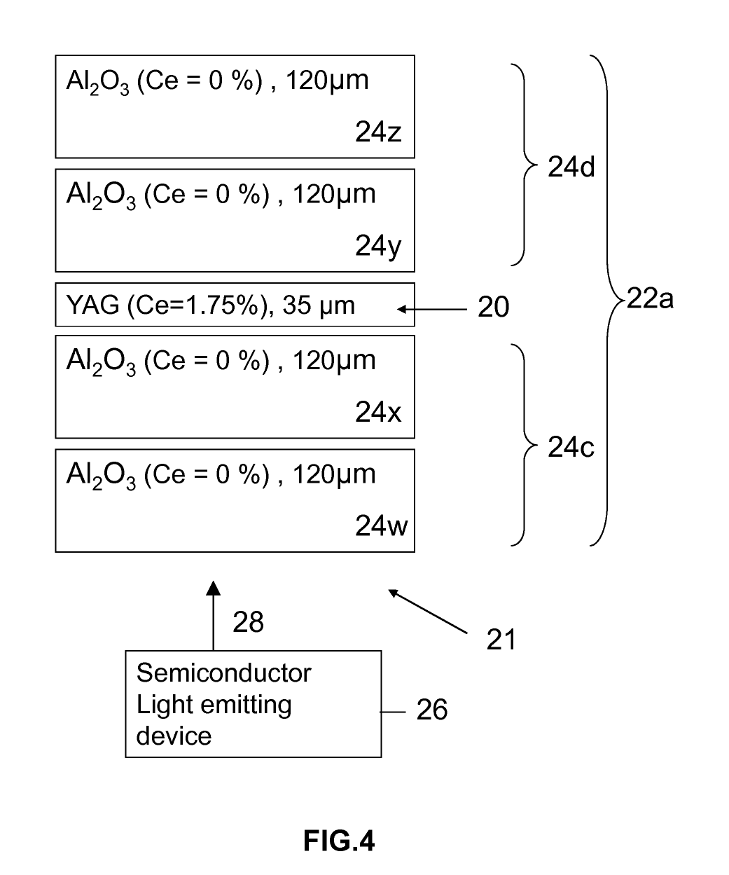

As shown in FIG. 4, one embodiment of the present invention provides a ceramic wavelength converting element 22 having at least a first emissive layer 20 having a garnet or garnet-like host material and an emissive guest material, and at least a first (24a) and second (24b) non-emissive blocking layers comprising a non-emissive blocking material having an ionic radius which is about 80% or less of that of the emissive guest material, the first emissive layer 20 disposed between the first (24a) and second (24b) non-emissive blocking layers. In one embodiment, the non-emissive blocking material has a metallic element. In one embodiment, the non-emissive blocking material is Al₂O₃.

In one embodiment, the emissive layer 20 is between about 10 to about 100 μm thick. In another embodiment, the thickness of the emissive layer 20 is between about 20-60 μm. In another embodiment, the thickness of the emissive layer 20 is between about 30-60 μm. In some embodiments, the guest or dopant concentration is in a range of about 0.5% to about 10.0% by mol (including about 0.8% to about 2.5% by mol) relative to yttrium as described later. In some embodiments, the guest or dopant concentration depends on the thickness of a YAG:Ce layer. In one embodiment, the guest or dopant concentration is about 1.75% for a YAG:Ce layer of about 35 μm. In another embodiment, the guest or dopant concentration is about 1.00% for a YAG:Ce layer of about 45 μm. The above may be applied to an emissive layer other than the YAG:Ce layer.

In one embodiment illustrated in FIG. 4, a light emitting device comprises a semiconductor light emitting device 21 comprising a laminated emissive composite 22 disposed adjacent to the light emitting source 26 in a path of light 28 emitted by the light source 26, the laminated emissive composite 22 further comprising at least a first emissive layer 20 having a garnet or garnet-like host material and an emissive guest material, and at least a first (24a) and second (24b) non-emissive blocking layers comprising a non-emissive blocking material having an ionic radius which is about 80% or less of that of the emissive guest material, the first emissive material disposed between the first and second non-emissive blocking layers. In some embodiments, the light emitting source 26 is a semi-conductor light emitting diode. In some embodiments, the light emitting source 26 is a semi-conductor light emitting diode comprising (AlInGa)N. In one embodiment, each of the at least first (24a) and second (24b) non-emissive blocking layers has a thickness greater than that of the emissive layer 20 (e.g., 30 to 400 μm or 50 to 200 μm), and the emissive layer and non-emissive blocking layers in the form of sintered ceramic tape cast layers. In another embodiment, the first and second non-emissive blocking layers are each comprised of plural non-emissive blocking layers (e.g., 2 to 5 layers each), e.g., 24z and 24y, and 24x and 24w, respectively. In another embodiment, each of the plural non-emissive blocking layers, e.g., the respective layers 24z, 24y, 24x and 24w, have a thickness greater than the emissive layer.

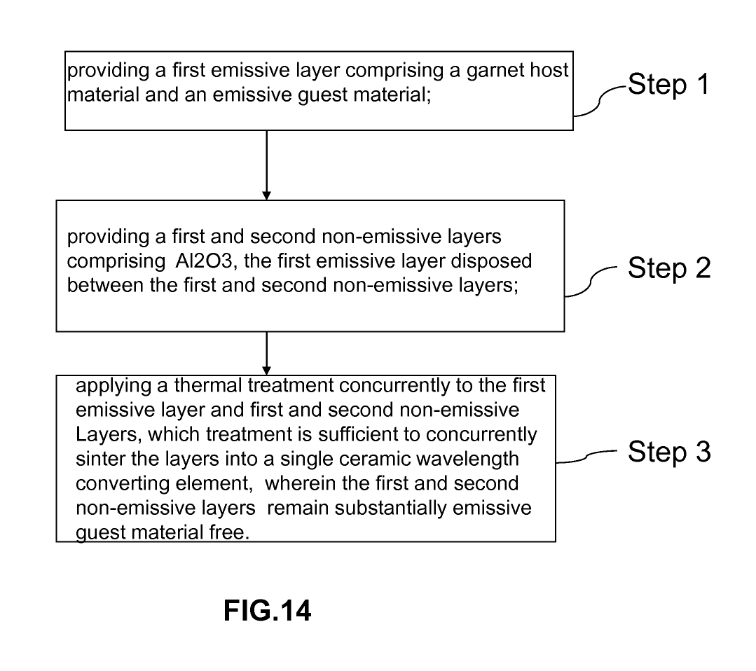

In another embodiment, as shown in FIG. 14, a method of making a ceramic wavelength converting element is described which comprises the steps of: providing an emissive layer having at least one garnet or garnet-like host material and at least one emissive guest material; and providing a first and second non-emissive blocking layers comprising at least one non-emissive blocking material having an ionic radius which is 80% or less of that of the emissive guest material; and applying a thermal treatment concurrently to the first emissive layer and first and second non-emissive blocking layers, said thermal treatment being sufficient to concurrently sinter the layers into a single wavelength converting element, wherein the first and second non-emissive blocking layers remain substantially or nearly free of migration of the emissive guest material. In one embodiment, the non-emissive blocking material comprises a metallic element having an ionic radius smaller than the ionic radius of the emissive guest material. In one embodiment, the emissive guest material comprises Ce and the non-emissive blocking material comprises Al₂O₃, e.g., Al has an ionic radius (0.050 nm, see Table 1 below) less than that of Ce (0.103 nm, see Table 1 below). In some embodiments, the steps of providing emissive layer(s) and non-emissive blocking layers include providing a cast tape comprising the emissive materials and providing a cast tape comprising the described non-emissive blocking materials. In some embodiments, the step of applying thermal treatment further includes stacking portions of the layers to produce a perform, heating the perform to produce a green perform, and sintering the green perform to concurrently sinter the emissive and non-emissive blocking materials to produce an emissive composite laminate. In some embodiments, the composite laminate comprises Al₂O₃/YAG:Ce/Al₂O₃ In one embodiment, the emissive and non-emissive blocking layers are both cast tape layers. In another embodiment, the emissive layer is a cast tape layer and the non-emissive blocking layer is a substrate comprising the non-emissive blocking material described above.

In one embodiment, the step of providing a cast tape formed of a non-emissive blocking material comprises mixing Al₂O₃ powder, dispersant, sintering aid, and organic solvent; milling the mixture using a milling ball of different than Al₂O₃ material to produce a milled first slurry; mixing a type 1 and type 2 plasticizer and organic binder into said first slurry to produce a second slurry; milling the second slurry to produce a milled second slurry; tape-casting the milled second slurry to produce a non-emissive cast tape; and drying the non-emissive containing cast tape to produce a non-emissive dried tape.

In one embodiment, the step of providing a cast tape formed of an emissive material having a garnet or garnet-like host material and an emissive guest material includes plasma-generating a phosphor nanoparticle having a weight average particle size of between 50 and about 500 nm; pre-annealing the phosphor nanoparticle at a temperature sufficient to substantially convert the nanoparticles to substantially all garnet or garnet-like phase phosphor nanoparticles; mixing the pre-annealed phosphor nanoparticles, dispersant, sintering aid, and organic solvent; ball-milling the mixture using a milling ball of material different than Y₂O₃ or Al₂O₃ material to produce a milled first slurry; mixing a type 1 and type 2 plasticizer and an organic binder into said first slurry to produce a second slurry; milling the second slurry to produce a milled second slurry; tape-casting the milled second slurry to produce a cast tape formed of an emissive material having a guest material having elements with a greater ionic radius than that of the elements of the non-emissive blocking layer elements with a greater ionic radius than that of the guest material; and drying the emissive material containing cast tape to produce an emissive dried tape.

### Materials

In one embodiment, the emissive material comprises a phosphor. The types of phosphors for the emissive phase of the sintered ceramic plate are chosen to achieve the desired or intended white point (i.e., color temperature) by taking the absorption and emission spectra of different types of phosphors into consideration. In some embodiments, the phosphor comprises a garnet or garnet-like material. In some embodiments, the emissive layer comprises a garnet or garnet-like host material and an emissive guest material. In some embodiments, a garnet or garnet-like structure refers to the tertiary structure of the inorganic compound. A garnet can crystallize in a cubic system, wherein the three axes are of substantially equal lengths and perpendicular to each other. This physical characteristic contributes to the transparency or other chemical or physical characteristics of the resulting material. A garnet or garnet-like structure can be described as A₃B₂C₃O₁₂, where the A cation (e.g., Y³⁺) is in a dodecahedral coordination site, the B cation (e.g., Al³⁺, Fe³⁺, etc.) is in an octahedral site, and the C cation (e.g., Al³⁺, Fe³⁺, etc.) is in a tetrahedral site.

The garnet or garnet-like material may be constituted by a composition A₃B₅O₁₂, wherein A and B are independently selected from trivalent metals. In some embodiments, A can be at least one selected from the following elements: Y, Lu, Ca, Gd, La, and Tb; and B can be at least one selected from the following elements: Al, Mg, Mn, Si, Ga, and In. Each A and B can be comprised of two or more elements. In some embodiments, the emissive layer includes a garnet or garnet-like host material and an emissive guest material. In some embodiments, the emissive guest material is substituted into the dodecahedral coordination site (A cation). In some embodiments, the A cation is selected from Y, Lu, Ca, Tb, and/or Gd. In some embodiments, Ce is substituted into the A site when Y is the primary A cation. In some embodiments, the emissive guest material is at least one rare earth metal. In some embodiments, the rare earth metal is selected from the group consisting of Ce, Nd, Er, Eu, Yb, Sm, Tb, Gd, and Pr. In some embodiments, the emissive guest material is substituted into an A cation coordination site. In some embodiments, the guest material is at least Ce. In some embodiments, the guest material further includes an emissive material selected from Nd, Eu, Cr, Sm, Tb, Gd, and Pr. Examples of useful phosphors include Y₃Al₅O₁₂:Ce, Lu₃Al₅O₁₂:Ce, Ca₃Sc₂Si₃O₁₂:Ce, Lu₂CaSi₃Mg₂O₁₂:Ce. Lu₂CaAl₄SiO₁₂:Ce, (Y, Tb)₃Al₅O₁₂:Ce, and/or (Y, Gd)₃(Al, Ga)₅O₁₂:Ce. In these examples, the A cation is Y, Lu, Ca, Lu/Ca, Y/Tb, or Y/Gd, respectively. In one embodiment, the phosphor material comprises plasma generated Y₃Al₅O₁₂:Ce³⁺ (YAG:Ce).

In some embodiments, the element constituting the non-emissive blocking material has an ionic radius which is 80% or less than that of the element constituting the emissive guest and/or the A cation element constituting the host material. In some embodiments, the non-emissive blocking material comprises a substantially transparent metal oxide material. In some embodiments, the transparent metal oxide material comprises a bi-elemental material or a monometal oxide material. In some embodiments, the material comprises a compound having the formula MₓO_{y}, wherein 1≦x≦3, and 1≦y≦8, wherein M is selected from one or any of Al, Ti, Si, and Ga. In some embodiments, the transparent metal oxide is selected from Al₂O₃, TiO₂, and/or SiO₂. In some embodiments, M is a B cation/element. In some embodiments, the transparent metal oxide is Al₂O₃. In some embodiments, the material is substantially free of the metallic garnet or garnet-like host element of the emissive layer. In some embodiments, the material is substantially free of the A cation/element. In some embodiments, the material comprises a metallic element having an ionic radius of less than that of the emissive guest material. In some embodiments, a substantially transparent metal oxide material refers to a material having at least 60%, 70%, 80%, 90% transmittance. Where the emissive guest material is Ce and the garnet or garnet-like host material is YAG, the non-emissive blocking material can be Al₂O₃. In other embodiments, the ionic radii of the elements of the non-emissive blocking material can be any one of less than 50%, 55%, 60%, 65%, 70%, 75%, or 80% of the ionic radii (Å or nm) of the elements of the emissive guest material and/or the A cation element constituting the host material. See for example the materials described in Table 1.

TABLE 1

| Material type | Elemental Material | Ionic Radius |
|---|---|---|
| Host A Cation | Y³⁺ | 0.093 nm |
| Host A Cation | Lu³⁺ | 0.085 nm |
| Host A Cation | Ca²⁺ | 0.099 nm |
| Emissive guest | Ce³⁺ | 0.103 nm |
| Emissive guest | Eu²⁺ | 0.095 nm |
| Emissive guest | Gd³⁺ | 0.094 nm |
| Emissive guest | Nd³⁺ | 0.100 nm |
| Emissive guest | Sm³⁺ | 0.096 nm |
| Emissive guest | Tb³⁺ | 0.092 nm |
| Emissive guest | Pr³⁺ | 0.101 nm |
| Non-emissive | Al³⁺ | 0.050 nm |
| Non-emissive | Ti⁴⁺ | 0.068 nm |
| Non-emissive | Si⁴⁺ | 0.041 nm |

Additional sources can be utilized to determine effective ionic radii of the respective elements (See, for example, Table 14, Effective Ionic Radii, pg, 4-123, Handbook of Chemistry and Physics, 81^{st} ed., CRC Press, New York, 2000; Shannon, R. D. and Prewitt, C. T., Acta Cryst. 25, 925 (1969); and Shannon, R. D. and Prewitt, C. T., Acta Cryst., 26, 1046 (1970), the disclosure of each of which is herein incorporated by reference). In some embodiments, any elements belonging to group 13 (such as Aluminum, Boron), group 14 (such as Silicon, Germanium), and group 4 (such as titanium, zirconium) can be used for the non-emissive blocking material.

In one embodiment, the selection of the garnet or garnet-like host, emissive guest material, and the non-emissive blocking material results in a wavelength converting element, wherein the emissive guest material substantially remains within the emissive layer, and the non-emissive blocking layer remains substantially free of the emissive guest material. The term “substantially free” of the guest material refers to the concentration of the emissive guest material in the non-emissive blocking layer as being any of the following: less than about 0.01%, less than about 0.001%, less than about 0.0001% for a distance of 10 μm, 20 μm, or 50 μm into the non-emissive blocking layer from the interface between the non-emissive blocking layer and the emissive layer.

In one embodiment, the emissive layer 20 comprises an emissive guest material at a concentration of between 0.05% to about 10.0% by mol. In another embodiment, the emissive layer 20 comprises an emissive guest material at a concentration of between 0.25% to about 5.0% by mol. In another embodiment, the emissive layer 20 comprises an emissive guest material at a concentration of between 0.5% to about 3.0% by mol. In another embodiment, the emissive layer 20 comprises an emissive guest material at a concentration of between 0.75% to about 2.75%, including, but not limited to, 1.00%, 1.5%, 1.75% or 2.00% by mol.

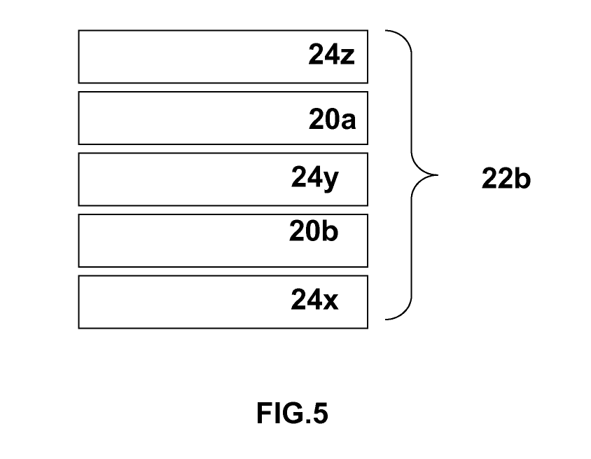

In one embodiment as shown in FIG. 5, the wavelength converting element 22 includes a first emissive layer 20a and further includes at least a second emissive layer 20b including a garnet or garnet-like host material and an emissive guest material, wherein at least one non-emissive blocking layer 24y is disposed between the first (20a) and second (20b) emissive layers. In some embodiments, the plural emissive layers include the same garnet or garnet-like host material and emissive guest material, e.g., YAG:Ce. In some embodiments, the plural emissive layers include the same emissive guest material, however, the guest materials in the plural emissive layers can be of differing concentrations, e.g., YAG:Ce (Ce 1.00%) and YAG:Ce (Ce 1.5%). In some embodiments, the plural emissive layers include different garnet or garnet-like host materials In some embodiments, the concentrations of the emissive guest materials is at least about 0.1 mol % greater, at least 0.5 mol % greater, or at least 1.0 mol % greater. In some embodiments, the emissive layer having a longer [redder] emissive peak wavelength is disposed closer to the light source. For example, for some warm white light applications, a first emissive layer comprising YAG:Ce (Ce=1.0%) and the second emissive layer comprises Lu₂CaMg₂Si₃O₁₂ (Ce=6.0%). In some embodiments, the plural emissive layers may each include different emissive guest materials.

In some embodiments, the emissive layer consists essentially of the garnet or garnet-like host material and the emissive guest material, and the non-emissive blocking layer consists essentially of the non-emissive transparent material, and further the following auxiliary elements can be added. A sintering aid can be included within the laminated emissive layers or non-emissive blocking layers or both during the method for making the same. In some embodiment, the sintering aid can be but not limited to tetraethoxysilane (TEOS), SiO_{2,} Zr or Mg silicates, colloidal silica, and/or mixtures thereof; oxides and fluorides such as but not limited to lithium oxide, titanium oxide, zirconium oxide, barium oxide, calcium oxide, magnesium oxide, strontium oxide, boron oxide, calcium fluoride, and/or mixtures thereof; preferably tetraethoxysilane (TEOS).

In some embodiments, a dispersant can be included within the laminated emissive layers or non-emissive blocking layers or both during the method for making the same. In some embodiments, the dispersants can be Flowen, fish oil, long chain polymers, steric acid; oxidized Menhaden fish oil, dicarboxylic acids such succinic acid, ethanedioic acid, propanedioic acid, pentanedioic acid, hexanedioic acid, heptanedioic acid, octanedioic acid, nonanedioic acid, decanedioic acid, o-phthalic acid, p-phthalic acid and/or mixtures thereof. Other dispersants that may be used include orbitan monooleate, preferably oxidized Menhaden fish oil (MFO).

In some embodiments, a binder can be included within the laminated emissive layers or non-emissive blocking layers or both during the method for making the same. In some embodiments, the organic binders can be Vinyl polymers such as but not limited to polyvinyl butyral (PVB), polyvinyl alcohol (PVA), polyvinyl chloride (PVC), polyvinyl acetate (PVAc), polyacrylonitrile, mixtures thereof and copolymers thereof, polyethyleneimine, poly methyl methacrylate (PMMA), vinyl chloride-acetate and/or mixtures thereof; preferably PVB.

In some embodiments, a plasticizer can be included within the laminated emissive layers or non-emissive blocking layers or both or the method for making the same. In some embodiments, the plasticizers can include Plasticizers type 1 which can generally decrease the Tg [transition glass temperature], e.g., making it more flexible, (such as phthalates including n-butyl (dibutyl) phthalate; dioctyl phthalate; butyl benzyl phthalate; and/or dimethyl phthalate), and Plasticizers type 2 which can enable more flexible, more deformable layers, and perhaps reduce the amount of voids resulting from lamnination (such as glycols including polyethylene glycol; polyalkylene glycol; polypropylene glycol; triethylene glycol; and/or dipropylglycol benzoate glycols).

Plasticizers Type 1, which may be employed in manufacture of transparent ceramic materials such as but not limited to transparent YAG, include but are not limited to butyl benzyl phthalate, dicarboxylic/tricarboxylic ester-based plasticizers such as but not limited to phthalate-based plasticizers such as but not limited to bis(2-ethylhexyl)phthalate, diisononyl phthalate, bis(n-butyl)phthalate, butyl benzyl phthalate, diisodecyl phthalate, di-n-octyl phthalate, diisooctyl phthalate, diethyl phthalate, diisobutyl phthalate, di-n-hexyl phthalate, and/or mixtures thereof; adipate-based plasticizers such as but not limited to bis(2-ethylhexyl)adipate, dimethyl adipate, monomethyl adipate, dioctyl adipate, and/or mixtures thereof; sebacate-based plasticizers such as but not limited to dibutyl sebacate, and maleate. Type 2 plasticizers such as but not limited to dibutyl maleate, diisobutyl maleate and/or mixtures thereof; polyalkylene glycols such as but not limited to polyethylene glycol, polypropylene glycol and/or mixtures thereof. Other plasticizers which may be used include but are not limited to benzoates, epoxidized vegetable oils, sulfonamides such as but not limited to N-ethyl toluene sulfonamide, N-(2-hydroxypropyl)benzene sulfonamide, N-(n-butyl)benzene sulfonamide, organophosphates such as but not limited to tricresyl phosphate, tributyl phosphate, glycols/polyethers such as but not limited to triethylene glycol dihexanoate, tetraethylene glycol diheptanoate and mixtures thereof; alkyl citrates such as but not limited to triethyl citrate, acetyl triethyl citrate, tributyl citrate, acetyl tributyl citrate, trioctyl citrate, acetyl trioctyl citrate, trihexyl citrate, acetyl trihexyl citrate, butyryl trihexyl citrate, trimethyl citrate, alkyl sulphonic acid phenyl ester, and/or mixtures thereof.

Solvents which may be used in manufacture of the emissive and non-emissive blocking layers include, but not limited to water, a lower alkanol such as but not limited to denatured ethanol, methanol, isopropyl alcohol, and/or mixtures thereof, preferably denatured ethanol, xylenes, cyclohexanone, acetone, toluene and methyl ethyl ketone, and/or mixtures thereof, preferably a mixture of xylenes and ethanol.

### Particle Size Adjustment

Raw material particles for tape casting in some embodiments are in nanometer scale. In order to avoid cracking of cast tapes caused by capillary force during evaporation of solvents, particle size of Al₂O₃ and synthesized YAG need to be in appropriate ranges. Particle size of YAG and Al₂O₃ can be adjusted by pre-annealing the particle in vacuum, O₂, H₂, H₂/N₂ and air in the temperature range of 800 to 1800° C., preferably in the range of 1000 to 1500° C., more preferably in the range of 1100 to 1400° C. Annealed particles have a BET surface area in the range of 0.5 to 20 m²/g, preferably in the range of 1-10 m²/g, more preferably in the range of 3 to 6 m²/g.

### Slurry Making

Described herein is a method to make slurry for fabricating yttrium aluminum garnet (YAG) and Al₂O₃ green sheets by tape casting according to some embodiments. Particles of YAG synthesized by plasma containing activators such as, but not limited to trivalent cerium ions, or Al₂O₃, are mixed with dispersant, sintering aids (if necessary) and solvents, and subsequently mixed by ball milling for 0.5 to 100 hrs, preferably 6 to 48 hrs, more preferably 12 to 24 hrs. This ball milled slurry is mixed with polymeric binder such as but not limited to polyvinyl butyral (PVB), plasticizers such as but not limited to Benzyl n-butyl phthalate (BBP) and polyethylene glycol (PEG). The average molecular weight of PEG is preferably in the range of 100 to 50000, more preferably in the range of 400 to 4000. Binders and plasticizers can be either directly added and mixed with slurry or be dissolved in advance in solvent then added to slurry.

The mixture is ball milled for 0.5 to 100 hrs, preferably 6 to 48 hrs, more preferably 12 to 24 hrs. The milling balls are, in one embodiment, comprised of a material different from the host material, e.g., if the host material is YAG, then the ball material can comprise ZrO₂. Slurry was passed through a filter to separate the ball and slurry. Viscosity of the slurry is adjusted to the range of 10 to 5000 centipoise (cP), preferably in the range of 50 to 3000 cP, more preferably in the range of 100 to 1000 centipoise (cP).

### Tape Casting

Described herein is a method of tape casting according to some embodiments. Slurry with appropriate viscosity is cast on a releasing substrate, for example, a silicone coated Mylar® (Polyethelene tetraphthalate) substrate, with a doctor blade with an adjustable gap. Thickness of cast tape can be adjusted by a doctor blade gap, slurry viscosity and casting rate. The cast tape is dried at ambient atmosphere with or without heating of the substrate. Green sheets with varied thickness are obtained after evaporation of solvent in cast tape. The gap of doctor blade can be changed in the range of 0.125 to 1.25 mm, preferably in the range of 0.25 to 1.00 mm, more preferably in the range of 0.375 to 0.75 mm. The casting rate is preferably in the range of about 10 to about 150 cm/min, more preferably in the range of 30 to 100 cm/min, more preferably in the range of 40 to 60 cm/min. In this way, the thickness of green sheets can be adjusted in the range of 20 to 300 micrometers.

### Lamination

Described herein is a method to produce composite of emissive and non-emissive green sheets by lamination according to some embodiments. Cast tapes comprising emissive and non-emissive blocking materials are cut into desired shape and dimension, and then assembled by stacking the single green sheets together. The total number of green sheets in stacking can be in the range of 2 to 100 depending on the thickness of a single green sheet and the activator concentration in an emissive layer. Stacking of cast tapes with the emissive layer located in top-most or bottom-most or between non-emissive blocking layers is placed in between metal dies, which are made of metals such as stainless steel, etc. Surface of metal dies in contact with laminated green sheets is mirror-like polished. The cast tape stacking is heated to above the Tg temperature of binders and then compressed uniaxially at pressure in the range of 1 to 500 MPa, preferably 30 to 60 MPa. The pressure and heat applied to green sheet stacking are kept for 1 to 60 min, preferably 30 min, more preferably 10 min, and then the pressure is released. In a further aspect, patterns in green sheets such as holes, tampered holes, pillars or roughness are formed on the green sheets by using dies with designed patterns in lamination. Such patterns can improve the light coupling and extraction in the direction of light output through reducing lateral light propagation by the waveguide effects.

### Firing

Described herein is a method of applying a thermal treatment concurrently to the first emissive layer and the first and second non-emissive blocking layers, which treatment is sufficient to concurrently sinter the layers into a single ceramic wavelength converting element, wherein the first and second non-emissive blocking layers remain substantially free of the emissive guest material, according to some embodiments. In some embodiments, the term “substantially free” of the emissive guest material refers to the concentration of the emissive guest material in the non-emissive blocking layers being less than about 0.01 mol %, less than about 0.001 mol %, less than about 0.0001 mol %, or less than a detectable level in the adjacent co-fired non-emissive blocking layer or being as insubstantial as impurities ordinarily associated with the other elements in the non-emissive blocking layer. The method of concurrently sintering laminated green sheets to a dense ceramic sheet is described herein. First, laminated green sheets disposed in the desired order, e.g., at least one emissive layer disposed between at least a first and second non-emissive blocking layers, are sandwiched between cover plates made of ZrO₂ (not limited to ZrO₂) with about 40% porosity to reduce the warping, cambering and bending of green sheets during debindering and sintering. A plurality of green sheets can be stacked between porous ZrO₂ cover plates alternatively. The green sheets are heated in air to decompose the organic components such as binders, plasticizers. The green sheets are then heated to a temperature in the range of 300 to 1100° C., preferably 500 to 900° C., more preferably 800° C. at rate of 0.01 to 10° C./min, preferably 0.05 to 5° C./min, more preferably 0.5 to 1.0° C./min, and kept for 30 to 300 min depending on the thickness of laminated green sheets.

After debindering, the green sheets are sintered in vacuum, H2/N2, H2, Ar/H2 at a temperature ranging from 1200° C. to 1900° C., preferably 1500° C. to 1800° C., more preferably 1600 to 1700° C., for duration from 1 hr to 100 hrs, preferably 2 to 10 hrs. The debindering and sintering can be carried out separately or operated at one step except atmosphere switching. The laminated green sheets sintered in reducing atmosphere are usually brownish or dark brown in color due to the formation of defects such as oxygen vacancy etc. during sintering. Re-oxidation in air or oxygen atmosphere is usually necessary to impart the ceramic sheet to high transmittance in a visible light wavelength range. Re-oxidation is conducted in the temperature range of 1000 to 1500° C. for 30 to 300 min at a heating rate of 1 to 20° C./min, preferably 1300° C. for 2 hrs at 5° C./min.

### Evaluation Method for Internal Quantum Efficiency (IQE) of Powder

The luminescence efficiency of phosphor powder can be evaluated by measuring the emission from the phosphor powder under the irradiation of standard excitation light with predetermined intensity. The internal quantum efficiency (IQE) of a phosphor is the ratio of the number of photons generated from the phosphor to the number of photons of excitation light which penetrate into the phosphor.

The IQE of a phosphor material can be expressed by the following formula:

$$InternalQuantumEfficiency = \frac{\int λ \cdot P ( λ ) d λ}{\int λ \cdot E ( λ ) \cdot [ 1 - R ( λ ) ] d λ}$$

$$ExternalQuantumEfficiency ( λ ) = InternalQuantumEfficiency ( λ ) \cdot [ 1 - R ( λ ) ]$$

$$Absorption ( λ ) = 1 - R ( λ )$$

where at any wavelength of interest λ, E(λ) is the number of photons in the excitation spectrum that are incident on the phosphor, R(λ) is the number of photons in the spectrum of the reflected excitation light, and P(λ) is the number of photons in the emission spectrum of the phosphor. This method of IQE measurement is also provided in Ohkubo et al., “Absolute Fluorescent Quantum Efficiency of NBS Phosphor Standard Samples,” 87-93, J. Illum Eng Inst. Jpn. Vol. 83, No. 2, 1999, the disclosure of which is incorporated herein by reference in its entirety.

### Method for Total Transmittance of Ceramic Composite

The total transmittance of the obtained ceramic composite can be measured by high sensitivity multi channel photo detector (MCPD 7000, Otsuka Electronics, Inc). First, a glass plate can be irradiated with continuous spectrum light from a halogen lamp source (150W, Otsuka Electronics MC2563) to obtain reference transmission data. Next the ceramic composite can be placed on the reference glass and irradiated. The transmitted spectrum will then be acquired by the photo detector (MCPD) for each sample. In this measurement, the ceramic composite on the glass plate can be coated with paraffin oil having the same refractive index as the glass plate. Transmittance at 800 nm wavelength of light can be used as a quantitative measure of transparency of the obtained ceramics composite.

Method for Determining the Diffusion between the Emissive and Non-Emissive blocking Layers

The laminated wavelength conversion element can be analyzed by static secondary ion mass spectroscopy to determine the diffusion of the emissive ions into the non-emissive blocking layer. Time of Flight secondary ion mass spectroscopy (Tof-Sims) can be used to analyze the diffusion of the emissive guest material into the non-emissive blocking layer. (See FIGS. 7 and 9).

### EXAMPLES

### IQE Measurement and Comparison of Powders

The present invention will be explained in detail with reference to Examples which are not intended to limit the present invention.

### 1). Plasma Generated YAG:Ce Powder Synthesis

56.36 g of Yttrium (III) nitrate hex hydrate (99.9% pure, Sigma-Aldrich), 94.92 g of Aluminum nitrate nonahydrate (>98% pure, Sigma-Aldrich), and 1.30 g of Cerium (III) nitrate hexahydrate (99.99% pure, Sigma-Aldrich) were dissolved in deionized water, followed by ultrasonication for 30 min to prepare a completely transparent solution.

This precursor solution of 2.0 M concentration was carried into a plasma reaction chamber similar to that shown in patent publication WO2008112710 A1 via an atomization probe using a liquid pump. The principle, technique and scope taught in the patent publication WO2008112710 A1 is hereby incorporated by reference in its entirety.

The synthesis experiment was conducted with an RF induction plasma torch (TEKNA Plasma System, Inc PL-35) being supplied with power from a Lepel RF Power Supply operating at 3.3 MHz. For the synthesis experiments, the chamber pressure was kept around 25 kPa-75 kPa, and the RF generator plate power was in the range of 10-30 kW. Both the plate power and the chamber pressure are user-controlled parameters. Argon was introduced into the plasma torch as both a swirling sheath gas (20-100 slm) and a central plasma gas (10-40 slm). Sheath gas flow was supplemented by addition of hydrogen (1-10 slm). Reactant injection was performed using a radial atomization probe (TEKNA Plasma System, Inc SDR-772) which operates on the principle of two-fluid atomization. The probe was positioned at the center of the plasma plume during reactant injection. The reactants were fed into the plasma plume by in-situ atomization at a rate of 1-50 ml/min during synthesis. Atomization of the liquid reactant was performed with Argon as atomizing gas delivered at a flow rate of 1-30 slm. The reactants when passing through the hot zone of the RF thermal plasma underwent a combination of evaporation, decomposition and nucleation. The nucleated particles were collected from the flow stream onto suitable porous ceramic or glass filters.

### Example 1

### YAG:Ce/Al2O3/YAG and YAG:Ce/YAG Ceramic Composite Preparation and Optical Performance Measurement

a. Plasma Raw Powder Used for YAG:Ce Green Sheet Preparation

Plasma synthesized YAG powder (5 g) containing 1.75 mol % cerium with respect to yttrium was added to a high purity alumina combustion boat and annealed in a tube furnace (MTI GSL 1600) at 1200° C. for about 2 hours under flowing gas mixture of 3% H₂ and 97% N₂. A BET surface area of annealed YAG powders was measured to be about 5.5 m²/g. The annealed YAG powder was used for YAG:Ce green sheet preparation.

b. Al₂O₃ Raw Powder Used for Al₂O₃ Green Sheet Preparation

Al₂O₃ (5 g, 99.99%, grade AKP-30, Sumitomo Chemicals Company Ltd.) with a BET surface area of of 6.6 m²/g was used for the Al₂O₃ green sheet preparation.

c. Solid State Reaction (SSR) Raw Powder Used for YAG Green Sheet Preparation

Y₂O₃ powder (2.846 g, 99.99%, lot N-YT4CP, Nippon Yttrium Company Ltd.) with a BET surface area of 4.6 m²/g, Al₂O₃ powder (2.146 g, 99.99%, grade AKP-30, Sumitomo Chemicals Company Ltd.) with a BET surface area of 6.6 m²/g were used at mole ratio of 3:5 for the SSR YAG green sheet preparation. No Ce contained in the SSR YAG sample.

d. Green Sheet Preparation and Lamination

A 50 ml high purity Al₂O₃ ball mill jar was filled with 30 g Y₂O₃ stabilized ZrO₂ ball of 3 mm diameter. Then 5 g of powder mixture as mentioned above (plasma YAG (1.75 mol % Ce), Al₂O₃, or SSR YAG), 0.10 g of dispersant (Flowlen G-700. Kyoeisha), 0.30 g of poly(vinyl butyral-co-vinyl alcohol-co-vinyl acetate) (Aldrich), 0.151 g of benzyl n-butyl phthalate (98%, Alfa Aesar) and 0.151 g polyethylene glycol (Mn=400, Aldrich), 0.025 g of tetraethyl orthosilicate as sintering aids (Fluka) (for the case of plasma and SSR YAG), 1.5 ml of xylene (Fisher Scientific, Laboratory grade) and 1.5 ml of ethanol (Fisher Scientific, reagent alcohol) were added in the jar. The slurry was produced by mixing the mixture by ball milling for about 24 hours.

When ball milling was completed, the slurry was then passed through a metal screen filter with pore size of 0.05 mm with a syringe and filter with metal housing. The obtained slurry was cast on a releasing substrate, e.g., silicone coated Mylar® carrier substrate (Tape Casting Warehouse) with an adjustable film applicator (Paul N. Gardner Company, Inc.) at a cast rate of 30 cm/min. The blade gap on a film applicator was set to get required thickness. Cast tape was dried at ambient atmosphere overnight to produce green sheet.

Dried cast tape comprising plasma YAG (1.75 mol % Ce), or Al₂O₃, or SSR YAG powders were cut into circular shape of 13 mm in diameter with a metal puncher. In one lamination, one piece of plasma YAG (1.75 mol % Ce) cut cast tape (90 μm), one piece of Al₂O₃ cut cast tape (50 μm) and two pieces of SSR YAG cut cast tapes (200 μm for each piece) were layered together with Al₂O₃ cast tape placed between the plasma YAG (1.75 mol % Ce) and SSR YAG layers (both SSR layers placed adjacent to each other). The layered composite was then placed between circular dies with mirror-polished surfaces and heated on hot plate to about 80° C., then compressed with hydraulic press machine at uniaxial pressure of 5 ton force and kept under pressure for about 5 minutes. A laminated composite of emissive and non-emissive blocking layers was produced.

For comparison experiment, in one lamination, one piece of plasma YAG (1.75 mol % Ce) cut cast tape (90 μm) and two pieces, placed adjacent to each other, of SSR YAG cut cast tapes (200 μm for each piece) were layered together and processed similarly as described above to get the laminated composite.

e. Sintering

Laminated green sheets were sandwiched between ZrO₂ cover plates (1 mm in thickness, grade 42510-X, ESL Electroscience Inc.) and placed on an Al₂O₃ plate of 5 mm thick. They were then heated in a tube furnace in air at rate of 0.5° C./min to about 800° C. and held for about 2 hours to remove the organic components from the green sheets to generate a preform. This process is named debindering.

After debindering, the performs were annealed at 1500° C. in a vacuum of 10⁻¹ Torr for about 5 hours at a heating rate of 1° C./min to complete conversion from non-garnet phases of YAG in non-emissive blocking layer, including, but not limited to amorphous yttrium oxides, YAP, YAM or Y₂O₃ and Al₂O₃ to yttrium aluminum garnet (YAG) phase and increase in YAG grain size.

Following the first annealing, the performs were further sintered in vacuum of 10⁻³ Torr at 1700° C. for about 5 hours at heating rate of 5° C./min and cooling rate of 10° C./min to room temperature to produce a transparent/translucent YAG ceramic sheet. When the laminated green sheets are annealed in the furnace with graphite heater and carbon felt lining, the performs were embedded in sacrifice YAG powders of 1 to 5 micrometers to prevent the samples from being partially reduced to constituent metals due to strong reducing atmosphere. Brownish sintered ceramic sheets were reoxidized in furnace at vacuum atmosphere at about 1400° C. for about 2 hours at heating and cooling rate of 10° C./min and 20° C./min respectively. The resulting sintered laminated composite exhibited transmittance of greater than 70% at 800 nm.

f. Optical Performance Measurement

Each ceramic sheet was diced into 2 mm×2 mm using a dicer (MTI, EC400).

Optical measurement was performed with Otsuka Electronics MCPD 7000 multi channel photo detector system together with required optical components such as optical fibers (Otuka Electronics), 12-inch diameter integrating spheres (Gamma Scientific, GS0IS12-TLS), calibration light source (Gamma Scientific, GS-IS12-OP1) configured for total flux measurement, and excitation light source (Cree blue-LED chip, dominant wavelength 455 nm, C455EZ1000-S2001).

Blue LED with peak wavelength of 455 nm was placed at the central position of the integrating sphere and was operated with a drive current of 25 mA. First the radiation power from the bare blue LED chip as excitation light was acquired. Next, a diced phosphor layer coated with paraffin oil having similar refractive index as common encapsulation resin such as epoxy was mounted on the LED chip. Then the radiation powder of the combination of the YAG phosphor layer and the blue LED were acquired.

### Example 2

Plural green sheets comprising SSR YAG (without the emissive guest materials, e.g., Ce) having a thickness of 200 μm each were produced by following the procedure set forth in EXAMPLE 1.

One green sheet of 90 μm comprising plasma YAG containing Ce³⁺ as an activator of 1.75 mol % with respect to yttrium was produced according to the procedures of EXAMPLE 1.

One green sheet of 50 um comprising Al₂O₃ was produced by following the procedures of EXAMPLE 1.

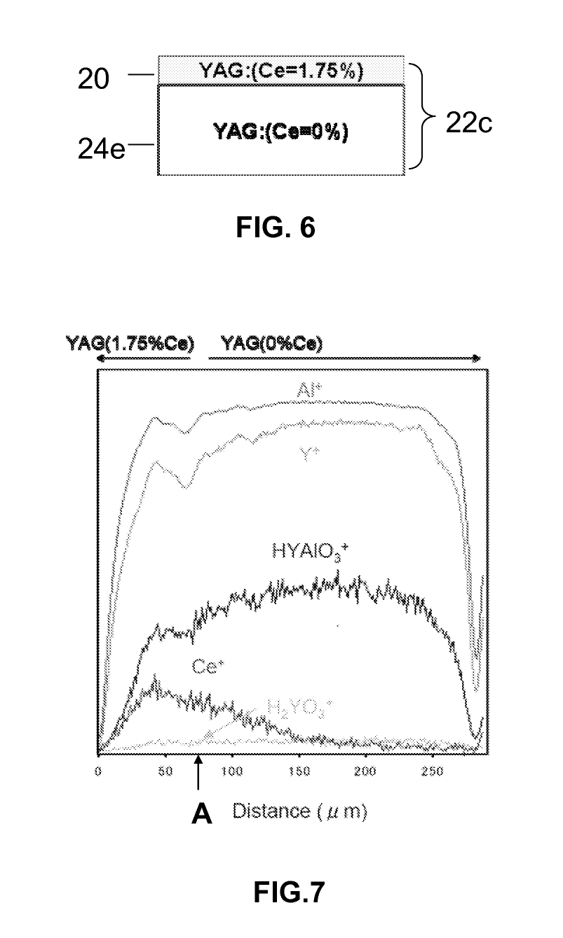

Two pieces of SSR YAG cut cast tapes (0% Ce, 200 μm each) and one piece of plasma YAG cut cast tape (1.75 mol % Ce, 90 μm) (YAG:Ce/SSR YAG 1/SSR YAG2) were used to get the first laminated green sheet. The first ceramic composite as shown in FIG. 6 was produced by following procedures in EXAMPLE 1 for debindering, first sintering, second sintering and reoxidation.

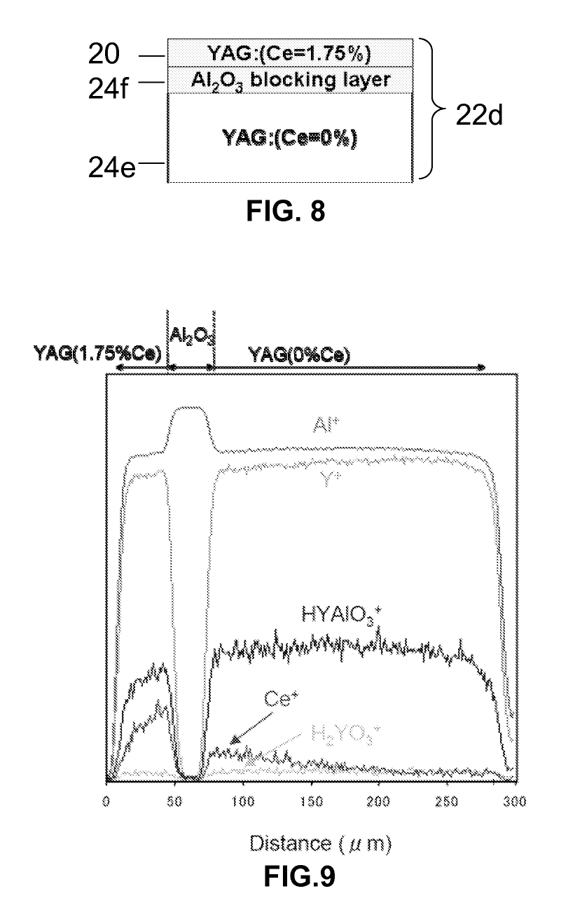

Two pieces of SSR YAG cut cast tapes (0% Ce, 200 μm each), one piece of Al₂O₃ cut cast tape (50 μm) and one piece of plasma YAG cut cast tape (1.75 mol % Ce, 90 um) were layered with the Al₂O₃ piece placed between the SSR YAG and the plasma YAG pieces (YAG:Ce/Al2O3/SSR YAG1/SSR YAG2) to get the second laminated green sheet. The second ceramic composite as shown in FIG. 8 was produced by following procedures in EXAMPLE 1 for debindering, first sintering, second sintering and reoxidation.

The compositions of the composite (FIG. 6) with configuration of YAG (1.75% Ce) 20/YAG (0% Ce) 24e were analyzed by TOF-SIMS (Time-Of-Flight Secondary Ion Mass Spectroscopy), and the results are shown in FIG. 7. As can be seen, Ce+ diffused into the YAG (0% Ce) layer as indicated by the tailing amount of Ce+ extending from about point A (the interface between the emissive and non-emissive blocking layers) into the non-emissive blocking layer at least about 100 μm. As a comparison, the compositions of the composite with configuration of YAG (1.75% Ce) 20/Al₂O₃ 24f/YAG (0% Ce) 24e (FIG. 8) were also analyzed by TOF-SIMS. As indicated in FIG. 9, the use of Al₂O₃ layer substantially blocked the diffusion of Ce resulting in a substantially guest material free non-emissive blocking layer. It is anticipated that with the utilization of a thicker Al₂O₃ non-emissive blocking layer (e.g., with a thickness greater than about 50 μm), the Ce diffusion can be fully prevented.

In addition, since the YAG (0% Ce) layer is usually thick and made of less expensive YAG powder with lower purity, the interdifussion of Ce would cause degraded optical performance of the whole composite and this potential concern can be minimized by utilizing Al₂O₃ as a replacement for YAG (0% Ce) layer.

### Example 3

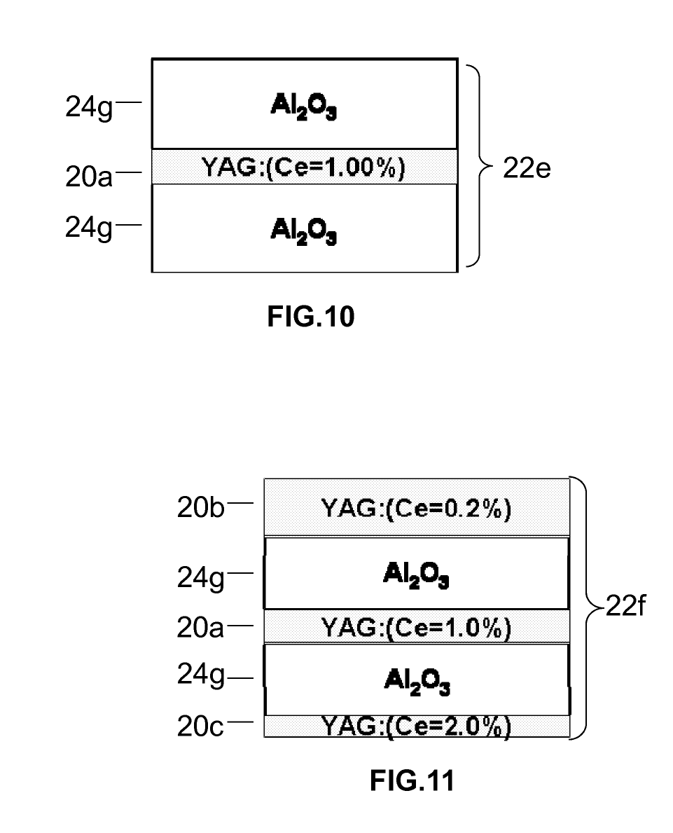

Two piece of Al₂O₃ cut cast tapes (120 μm each) 24g and one piece of plasma YAG cut cast tape (1.00 mol % Ce, 45 μm) 20a are layered with the plasma YAG piece placed between the Al₂O₃ pieces to get the laminated green sheet (FIG. 10). The ceramic composite are produced by following procedures in EXAMPLE 1 for debindering, first sintering, second sintering and reoxidation. TOF-SIMS (Time-Of-Flight Secondary Ion Mass Spectroscopy) will be performed for composition analysis. With the current thickness of Al₂O₃ sheet, it is anticipated that Ce will be fully constrained with the plasma YAG layer even though the used Ce doping concentration can be as high as 1.00 mol %.

### Example 4

Two piece of Al₂O₃ cut cast tapes (120 μm each) 24g, one piece of plasma YAG cut cast tape (0.2 mol % Ce, 120 μm) 20b, one piece of plasma YAG cut cast tape (1.0 mol % Ce, 50 μm) 20a, and one piece of plasma YAG cut cast tape (2.0 mol % Ce, 35 μm) 20c are layered with the Al₂O₃ piece placed between each plasma YAG piece to get the laminated green sheet, as shown in FIG. 11. The ceramic composite will be produced by following procedures in EXAMPLE 1 for debindering, first sintering, second sintering and reoxidation.

Optical properties are evaluated with same method as EXAMPLE 1,

### Example 5

Plural green sheets comprising Al₂O₃ having a thickness of 200 μm each are produced by following the procedure set forth in EXAMPLE 1.

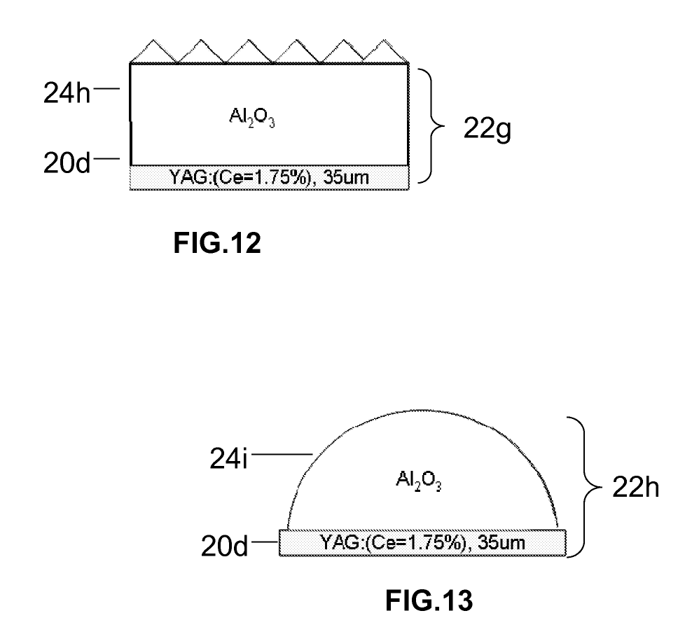

One green sheet of 50 μm formed of plasma YAG powder containing Ce³⁺ as an activator of 1.75 mol % with respect to yttrium is produced and layered with an Al₂O₃ piece according to the procedures of EXAMPLE 1. Laminated green sheets consisting of the green sheet 20d with the Al₂O₃ layer 24h are produced by following the procedures as in EXAMPLE 1 except that a die with pattern of arrayed pyramids or prisms are set forth to the side of layer without activator. The ceramic composites are produced by following procedures in EXAMPLE 1 for debindering, first sintering, second sintering (FIG. 12).

Optical properties are evaluated with same method as EXAMPLE 1,

### Example 6

One green sheet of 50 μm formed of plasma YAG powder containing Ce³⁺ as activator of 2.0 mol % with respect to yttrium is produced and layered with an Al₂O₃ piece according to the procedures of EXAMPLE 1. Laminated green sheets consisting of the green sheet 20d with the Al₂O₃ layer 24i are produced by following the procedures as in EXAMPLE 1, followed by bonding to a bulk hemisphere ceramic lens with designed curvature, which is produced by slip casting, vacuum casting, centrifugal casting, dry pressing, gelcasting, hot pressure casting, hot injection molding, extrusion, isostatic pressing followed by debindering and sintering at elevated temperature and controlled atmosphere. Bonding materials comprises polymers, low melting point glasses, ceramics (FIG. 13).

It will be appreciated by those skilled in the art that various omissions, additions and modifications may be made to the processes described above without departing from the scope of the invention, and all such modifications and changes are intended to fall within the scope of the invention.

What is claimed is:

1. A ceramic wavelength converting element comprising:
at least a first emissive layer comprising a garnet or garnet-like host material and an emissive guest material; and
at least a first non-emissive blocking layer comprising a non-emissive blocking material consisting essentially of elements having ionic radii which are about 80% or less of an ionic radius of an A cation element when the garnet or garnet-like host material is expressed as A₃B₅O₁₂ and/or an element constituting the emissive guest material,
wherein the first emissive layer and first non-emissive blocking layer are disposed in contact with each other and sintered together, and the first non-emissive blocking layer is substantially free of the emissive guest material migrated through an interface between the first emissive layer and the first non-emissive blocking layer.

2. The ceramic wavelength converting element of claim 1, wherein the first emissive layer has a thickness of less than about 200 μm.

3. The ceramic wavelength converting element of claim 1, wherein the non-emissive blocking layer consists essentially of a bi-elemental material.

4. The ceramic wavelength converting element of claim 3, wherein the bi-elemental material is Al₂O₃.

5. The ceramic wavelength converting element of claim 1, wherein the garnet host material is selected from the group consisting of Y₃Al₅O₁₂, Lu₃Al₅O₁₂, Ca₃Sc₂Si₃O₁₂, (Y,Tb)₃Al₅O₁₂ and (Y, Gd)₃(Al, Ga)₅O₁₂, Lu₂CaSi₃Mg₂O₁₂, and Lu₂CaAl₄SiO₁₂.

6. The ceramic wavelength converting element of claim 1, wherein the element constituting the emissive guest material comprises Ce.

7. The ceramic wavelength converting element of claim 6, wherein the element constituting the emissive guest material further comprises Mn, Nd, Er, Eu, Cr, Yb, Sm, Tb, Gd, and/or Pr.

8. The ceramic wavelength converting element of claim 1, further comprising a second non-emissive blocking layer comprising a non-emissive blocking material, wherein a metallic element constituting the second non-emissive blocking material has an ionic radius which is about 80% or less of an ionic radius of the A cation element when the garnet or garnet-like host material is expressed as A₃B₅O₁₂ and/or the element constituting the emissive guest material, wherein the first emissive layer is disposed between and in contact with the first and second non-emissive blocking layers, and sintered together, and the second non-emissive blocking layer is substantially free of the emissive guest material migrated through an interface between the first emissive layer and the second non-emissive blocking layer.

9. The ceramic wavelength converting element of claim 1, wherein the first non-emissive blocking layer comprises multiple sublayers of the non-emissive blocking material.

10. The ceramic wavelength converting element of claim 9, wherein the first emissive layer and each sublayer of the first non-emissive blocking layer are ceramic cast tapes.

11. The ceramic wavelength converting element of claim 1, further comprising a second emissive layer comprising a garnet host material and an emissive guest material, wherein at least one non-emissive blocking layer is disposed between and in contact with the second and first emissive layers.

12. The ceramic wavelength converting element of claim 11 wherein the first and second emissive layers comprise the same garnet host material and emissive guest material.

13. The ceramic wavelength converting element of claim 11, wherein the first and second emissive layers comprise different garnet host materials.

14. The ceramic wavelength converting element of claim 13, wherein the first and second emissive layers comprise the same emissive guest material.

15. The ceramic wavelength converting element of claim 14, wherein the first and second emissive layers have the same emissive guest material concentration.

16. The ceramic wavelength converting element of claim 14, wherein the first and second emissive layers have different emissive guest material concentrations.

17. The ceramic wavelength converting element of claim 1, wherein the emissive guest material has a concentration of about 0.05% to about 10.0% by mol relative to a metallic element at the dodecahedral coordination site of the garnet host material.

18. A semiconductor light emitting device comprising:
a light emitting source providing an emitted radiation; and
the ceramic wavelength converting element of any one of claims 1-17, wherein the ceramic wavelength converting element is positioned to receive the radiation emitted from the light emitting source.

19. A method of making the ceramic wavelength converting element of claim 1, comprising:
providing a first emissive layer comprising a garnet or garnet-like host material and an emissive guest material;
providing a first non-emissive blocking layer comprising a non-emissive blocking material, wherein a metallic element constituting the non-emissive blocking material has an ionic radius which is about 80% or less of an ionic radius of an A cation element when the garnet or garnet-like host material is expressed as A₃B₅O₁₂ and/or an element constituting the emissive guest material;
disposing the first emissive layer and the first non-emissive blocking layer in contact with each other; and
applying a thermal treatment concurrently to the first emissive layer and first non-emissive blocking layer, said treatment being sufficient to concurrently sinter the layers into a single ceramic wavelength converting element, wherein the first non-emissive blocking layer is substantially free of the emissive guest material migrated through an interface between the first emissive layer and the first non-emissive blocking layer.

20. The method of claim 19, wherein the garnet host material is YAG.

21. The method of claim 19, wherein the element constituting the emissive guest material comprises Ce.

22. The method of claim 21, wherein the emissive guest material has a concentration of about 0.05% to about 10.0% by mol relative to a metallic element at the dodecahedral coordination site of the garnet host material.
